(19) United States
(12) Patent Application Publication
(10) Pub. No.: US 2026/0123491 A1
(43) Pub. Date: Apr. 30, 2026

(54) WIRING BOARD, SEMICONDUCTOR MODULE INCLUDING THE SAME, AND A METHOD OF MANUFACTURING THE SAME

(71) Applicant: Samsung Electronics Co., Ltd., Suwon-si (KR)

(72) Inventor: Junseo LEE, Suwon-si (KR)

(73) Assignee: Samsung Electronics Co., Ltd., Suwon-si (KR)

(21) Appl. No.: 19/003,603

(22) Filed: Dec. 27, 2024

(30) Foreign Application Priority Data
Aug. 29, 2024 (KR) 10-2024-0116986

(51) Int. Cl. H01L 23/498; H05K 1/02

(52) U.S. Cl. CPC H10W 70/69; H05K 1/0274

(57) ABSTRACT

A wiring board may include a first insulating layer, a reflective layer disposed on an upper surface of the first insulating layer, a conductive pattern on an upper surface of the reflective layer, and a protective layer on the upper surface of the reflective layer and having an opening exposing at least a portion of the conductive pattern, wherein the reflective layer includes a second insulating layer and particles dispersed in the second insulating layer, each of the particles includes a core portion and a shell portion surrounding the core portion, and a light reflectivity of the core portion is higher than a light reflectivity of the shell portion.

### CROSS-REFERENCE TO RELATED APPLICATIONS

This U.S. non-provisional patent application claims priority under 35 U.S.C. § 119 to Korean Patent Application No. 10-2024-0116986 filed on Aug. 29, 2024, in the Korean Intellectual Property Office, the entire contents of which are hereby incorporated by reference.

### BACKGROUND OF THE INVENTION

The inventive concept relates to a wiring board, a semiconductor module including the same, and a method of manufacturing the same.

Recently, for a printed circuit board (PCB) used as a wiring board, it may be necessary to meet high-speed and high-density characteristics that may be required in the electronics industry. To do this, many difficult requirements for the PCB may need to be solved, such as small linewidths, excellent electric characteristics, high reliability, high-speed signal transmission, and high-functionality.

A semiconductor package and a semiconductor module are provided to implement an integrated circuit chip to qualify for use in electronic products. The semiconductor module includes a semiconductor package and a wiring board mounted thereon. In a typical semiconductor package, a semiconductor chip may be mounted on a printed circuit board (PCB), and may be electrically connected to the PCB through bonding wires or bumps. Semiconductor chips are gradually becoming compact with the continuous development of semiconductor technology. Alternatively, various functions are integrated into a single semiconductor chip. Therefore, semiconductor chips have a great number of input/output pads on a small area. Various studies are conducted to improve structural stability and electrical characteristics without pattern abnormality.

### SUMMARY

An object of the inventive concept is to provide a wiring board with improved structural stability, a semiconductor module including the same, and a method of manufacturing the same.

An object of the inventive concept is to provide an electronic system including a semiconductor device.

A wiring board according to some embodiments of the inventive concept may include a first insulating layer, a reflective layer disposed on an upper surface of the first insulating layer, a conductive pattern on an upper surface of the reflective layer, and a protective layer on the upper surface of the reflective layer and having an opening exposing at least a portion of the conductive pattern. The reflective layer may include a second insulating layer and particles dispersed in the second insulating layer. Each of the particles includes a core portion and a shell portion surrounding the core portion. A light reflectivity of the core portion may be higher than a light reflectivity of the shell portion.

A wiring board according to some embodiments of the inventive concept may include a first insulating layer, a conductive pattern on an upper surface of the first insulating layer, a reflective pattern on the upper surface of the first insulating layer, and a protective layer disposed on at least a portion of the reflective pattern on the first insulating layer. The protective layer may have an opening exposing at least a portion of the conductive pattern, and an inner wall of the opening may be separated from the upper surface of the first insulating layer by the reflective pattern or the conductive pattern. The reflective pattern may include a second insulating layer and particles dispersed in the second insulating layer. Each of the particles includes a core portion and a shell portion surrounding the core portion.

A method of manufacturing a wiring board according to some embodiments of the inventive concept may include forming a conductive pattern on an upper surface of a first insulating layer, forming a reflective layer on the upper surface of the first insulating layer, patterning the reflective layer to form a reflective pattern, forming a protective layer covering the conductive pattern and the reflective pattern on the first insulating layer, and performing an exposure process and a development process on the protective layer to form an opening exposing at least a portion of the conductive pattern. An inner wall of the opening may be disposed on an upper surface of the reflective pattern. The reflective pattern may include a second insulating layer and particles dispersed in the second insulating layer. Each of the particles may include a core portion and a shell portion surrounding the core portion. A light reflectivity of the core portion may be greater than a light reflectivity of the shell portion.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view for explaining a wiring board according to embodiments of the inventive concept.

FIG. 2 is a plan view for explaining a wiring board according to embodiments of the inventive concept.

FIG. 3 is an enlarged view of region ‘A’ of FIG. 1.

FIGS. 4 to 6 are views for explaining particles of a reflective layer.

FIG. 7 is a cross-sectional view for explaining a wiring board according to embodiments of the inventive concept.

FIG. 8 is a plan view for explaining a wiring board according to embodiments of the inventive concept.

FIG. 9 is a cross-sectional view for explaining a wiring board according to embodiments of the inventive concept.

FIG. 10 is a plan view for explaining a wiring board according to embodiments of the inventive concept.

FIG. 11 is an enlarged view of region ‘B’ of FIG. 9.

FIGS. 12 and 13 are cross-sectional views for explaining a wiring board according to embodiments of the inventive concept.

FIG. 14 is a plan view for explaining a wiring board according to embodiments of the inventive concept.

FIG. 15 is an enlarged view of region ‘C’ of FIG. 13.

FIGS. 16 and 17 are cross-sectional views for explaining a wiring board according to embodiments of the inventive concept.

FIGS. 18 and 19 are cross-sectional views for explaining a semiconductor module according to embodiments of the inventive concept.

FIGS. 20 to 29 are cross-sectional views for explaining a method of manufacturing a wiring board of the inventive concept.

### DETAILED DESCRIPTION

A wiring board according to the inventive concept is described with reference to the drawings.

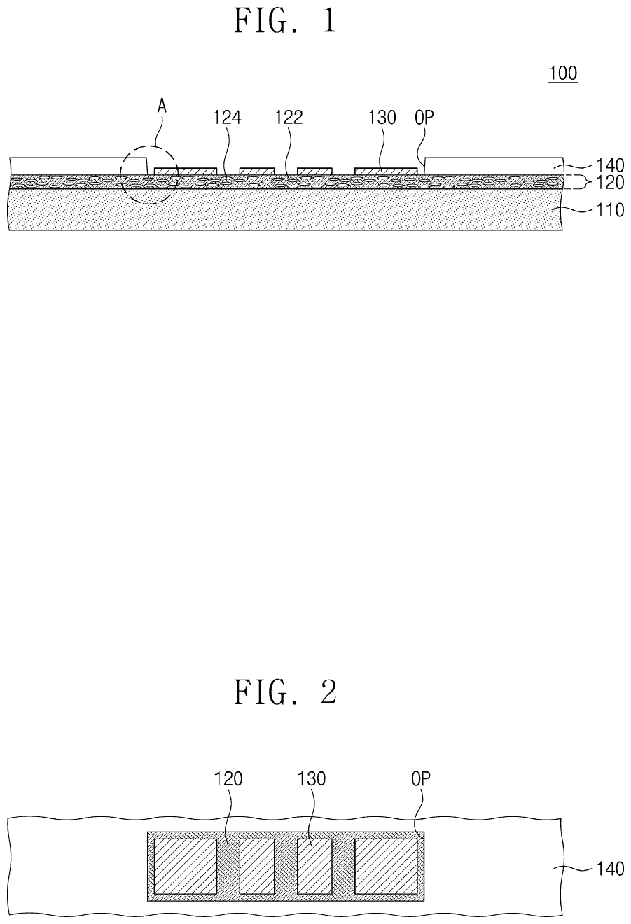

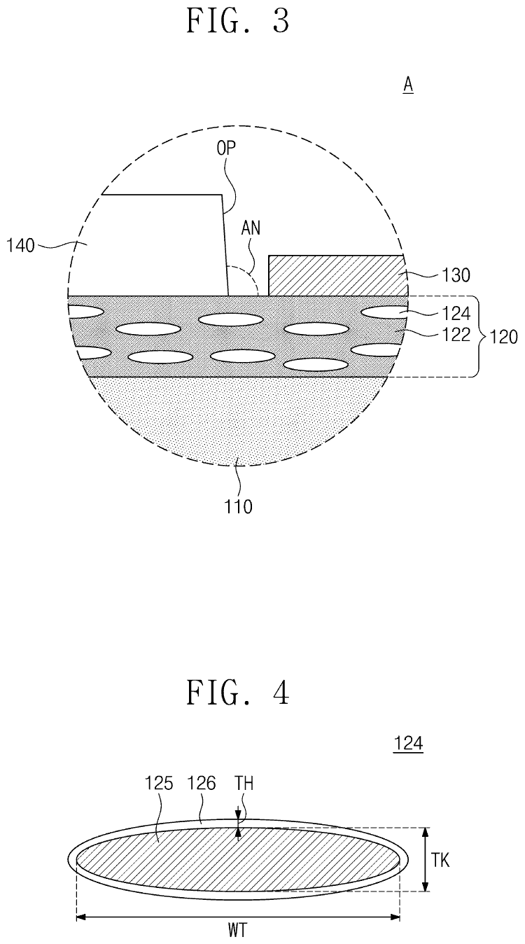

FIG. 1 is a cross-sectional view for explaining a wiring board according to embodiments of the inventive concept. FIG. 2 is a plan view for explaining a wiring board according to embodiments of the inventive concept. FIG. 3 is an enlarged view of region ‘A’ of FIG. 1. FIGS. 4 to 6 are views for explaining particles of a reflective layer and cross-sectional views of the particles, respectively.

Referring to FIGS. 1 and 2, a wiring board 100 may be provided. The wiring board 100 may be a printed circuit board (PCB) or a redistribution board.

A first insulating layer 110 may be provided. The first insulating layer 110 may be one of insulating patterns provided in the wiring board 100. In detail, the first insulating layer 110 may be an insulating pattern provided at the uppermost one of the insulating patterns. For example, when the wiring board 100 is a printed circuit board, the wiring board 100 may include a core portion and peripheral portions provided on upper and lower surfaces of the core portion, respectively. The peripheral portions may include insulating patterns and wiring patterns provided in the insulating patterns. The first insulating layer 110 may be an insulating pattern disposed at the outermost surface among the insulating patterns of the peripheral portions. The core portion may include an insulating material such as glass fiber, a ceramic plate, epoxy, or resin. Alternatively, the core portion may include stainless steel, aluminum (Al), nickel (Ni), magnesium (Mg), zinc (Zn), tantalum (Ta), or a combination thereof. The core portion may have a vertical connection terminal that vertically penetrates the core portion and electrically connects the peripheral portions. Alternatively, when the wiring board 100 is a redistribution board, the wiring board 100 may include wiring layers that are vertically stacked. Each of the wiring layers may include an insulating pattern and a wiring pattern provided on the insulating pattern. The first insulating layer 110 may be an insulating pattern of a wiring layer disposed at the uppermost one of the wiring layers.

The first insulating layer 110 may include an insulating material. For example, the first insulating layer 110 may include prepreg, Ajinomoto Build-up film (ABF), FR-4, or Bismaleimide Triazine (BT).

Referring to FIGS. 1 to 3, a reflective layer 120 may be provided on the first insulating layer 110. The reflective layer 120 may cover an upper surface of the first insulating layer 110. The reflective layer 120 may include a second insulating layer 122 and particles 124.

The second insulating layer 122 may be provided on the first insulating layer 110. The second insulating layer 122 may cover the upper surface of the first insulating layer 110. The second insulating layer 122 may include the same material as the first insulating layer 110. The second insulating layer 122 may include an insulating material. For example, the second insulating layer 122 may include prepreg, Ajinomoto Build-up Layer (ABF), FR-4, or Bismaleimide Triazine (BT). However, the inventive concept is not limited thereto. The second insulating layer 122 may include a different material from the first insulating layer. According to another embodiments, the second insulating layer 122 may include an insulating polymer or a photo imageable dielectric (PID). For example, the photosensitive insulating material may include at least one of photosensitive polyimide (PI), polybenzoxazole (PBO), phenol-based polymer, or benzocyclobutene-based polymer.

The particles 124 may be provided in the second insulating layer 122. The particles 124 may be dispersed in the second insulating layer 122. The particles 124 may be provided at a volume fraction of 0.1% to 50% with respect to a volume of the second insulating layer 122. The particles 124 may have a plate shape. In the present specification, the plate shape may mean a flat shape. For example, the particles 124 may have two major axes intersecting each other and may have a minor axis perpendicular to the major axes. The major axes of the particles 124 may be substantially parallel to an upper surface of the reflective layer 120, preferably, to an upper surface of the second insulating layer 122. Alternatively, the major axes of the particles 124 may be substantially parallel to a lower surface of the reflective layer 120, preferably, to a lower surface of the second insulating layer 122 or the upper surface of the first insulating layer 110. That is, the particles 124 may lie in a direction substantially parallel to the upper surface of the reflective layer 120. In other words, a thickness of each of the particles 124 in a direction perpendicular to the upper surface of the reflective layer 120 may be smaller than a width of each of the particles 124 in a direction parallel to the upper surface of the reflective layer 120. Each of the particles 124 may have a flat ellipsoid shape. However, the inventive concept is not limited thereto. Each of the particles 124 may have a core portion 125 and a shell portion 126.

One or ordinary skill in the art would understand that the expression “substantially parallel” may mean not only being exactly parallel (0°) but also being close to parallel including process errors, positional deviations, and/or measurement errors that may occur in a manufacturing process, and the range thereof may be widely accepted in the art. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

According to exemplary embodiments of the present disclosure, the term “reflective layer” used herein may not necessarily mean a continuous layer with no discrete opening(s), which are shown in FIGS. 1 and 7, and may also refer to a reflective pattern having discrete opening(s) therein, which are shown in FIGS. 9, 12, 13, 16 and 17. The terms “reflective layer” and “reflective pattern” may be merely named for distinguishing reflective materials formed on an insulating layer in different steps before and after a patterning process of a preliminary reflective layer in manufacturing a wiring board, and can be used in a mixed-up manner.

Referring to FIG. 4, configuration of the particles 124 will be described in detail based on one particle 124.

The core portion 125 may have a shape such as a bead, a wire, or a rod. The core portion 125 may have a plate shape. Major axes of the core portion 125 may be parallel to the upper surface of the reflective layer 120. Alternatively, the major axes of the core portion 125 may be parallel to the lower surface of the reflective layer 120. That is, the core portion 125 may lie in a direction parallel to the upper surface of the reflective layer 120. In other words, a thickness TK of the core portion 125 in the direction perpendicular to the upper surface of the reflective layer 120 may be smaller than a width WT of the core portion 125 in the direction parallel to the upper surface of the reflective layer 120. The thickness TK of the core portion 125 may be 0.01 micrometer to 1 micrometer. The width WT of the core portion 125 may be 0.1 micrometer to 10 micrometers. The core portion 125 may include a material having high light reflectivity. For example, the core portion 125 may include a metal material. As an example, the metal material may include chromium (Cr) or silver (Ag).

According to embodiments of the inventive concept, the particles 124 provided in the reflective layer 120 may have the core portion 125 having high light reflectivity. Accordingly, process defects in a patterning process of a protective layer 140 described later in the manufacturing process of the wiring board 100 may be reduced. This will be described in detail in the manufacturing process of the wiring board 100 described later.

In addition, the core portion 125 in the reflective layer 120 may have a plate shape, and the core portion 125 may include a metal material. Accordingly, heat may be easily transferred along the particles 124 in a horizontal direction in the reflective layer 120. That is, heat transfer in the horizontal direction in the wiring board 100 may be facilitated, and the wiring board 100 with improved heat dissipation efficiency and a semiconductor module including the same may be provided.

The shell portion 126 may surround the core portion 125. In detail, the shell portion 126 may cover an outer surface of the core portion 125. In other words, the core portion 125 may be embedded in the shell portion 126. The core portion 125 may not be exposed on an outer surface of the shell portion 126. A thickness TH of the shell portion 126 may be 10 nanometers to 500 nanometers. Here, the thickness TH of the shell portion 126 means the distance from the outer surface of the core portion 125 to an outer surface of the shell portion 126 in a direction perpendicular to the outer surface of the core portion 125. A light reflectivity of the shell portion 126 may be smaller than a light reflectivity of the core portion 125. The shell portion 126 may include an insulating material. The shell portion 126 may include a transparent material. For example, the shell portion 126 may include a prepreg, a transparent polymer, or a transparent ceramic.

According to embodiments of the inventive concept, the particles 124 provided in the reflective layer 120 have insulating characteristics and the transparent shell portion 126 may surround the core portion 125. Accordingly, an electrical short circuit due to the core portion 125 in the reflective layer 120 may not occur. That is, the wiring board 100 with improved electrical characteristics and a semiconductor module including the same may be provided.

FIG. 4 illustrates a surface of the core portion 125 of the particles 124 is smooth, but the inventive concept is not limited thereto.

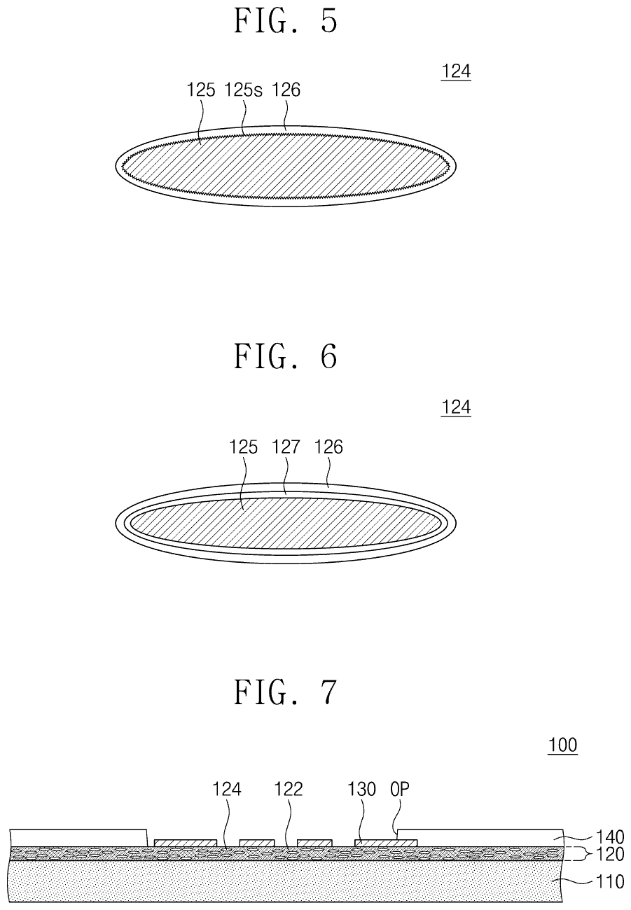

According to other embodiments, as illustrated in FIG. 5, an outer surface 125s of the core portion 125 of the particles 124 may have a rough surface. For example, a surface roughness of the outer surface 125s of the core portion 125 may be greater than a surface roughness of the outer surface of the shell portion 126. A separate process, such as etching, may be performed on the outer surface 125s of the core portion 125 to increase the surface roughness of the outer surface 125s of the core portion 125.

According to embodiments of the inventive concept, as the roughness of the outer surface 125s of the core portion 125 is large, adhesion of the shell portion 126 to the outer surface 125s of the core portion 125 may be improved. Accordingly, the shell portion 126 may not be separated from the core portion 125, and electrical insulation characteristics provided by the shell portion 126 to the particles 124 may be improved.

According to other embodiments, as illustrated in FIG. 6, an intermediate layer 127 may be interposed between the core portion 125 and the shell portion 126 of the particles 124. The intermediate layer 127 may be provided to improve adhesive strength between the core portion 125 and the shell portion 126. For example, the intermediate layer 127 may have a silane bonding group. A silane treatment may be performed on the outer surface of the core portion 125 to form the intermediate layer 127.

According to embodiments of the inventive concept, as the intermediate layer 127 more firmly bonds the core portion 125 and the shell portion 126, the shell portion 126 may not be separated from the core portion 125, and electrical insulation characteristics provided by the shell portion 126 to the particles 124 may be improved.

Referring again to FIGS. 1 to 3, a conductive pattern 130 may be disposed on the reflective layer 120. The conductive pattern 130 may be disposed on the upper surface of the reflective layer 120. The conductive pattern 130 may include a circuit pattern. The conductive pattern 130 may be used as a connection pattern for redistributing a device mounted on the wiring board 100. For example, the conductive pattern 130 may be a pad for mounting an electronic device such as a semiconductor chip on the wiring board 100, or a wiring pattern for providing an electrical connection to the pad. The conductive pattern 130 may include one selected from copper (Cu), aluminum (Al), silver (Ag), tin (Sn), gold (Au), nickel (Ni), lead (Pb), titanium (Ti), or a combination thereof.

Although not illustrated in detail, the conductive pattern 130 may include circuit patterns, and thus may be electrically connected to core patterns or other wiring patterns provided in or below the first insulating layer 110. For example, vias may be provided that vertically penetrate the first insulating layer 110 and the reflective layer 120, and the vias may connect the conductive pattern 130 and the wiring patterns.

A protective layer 140 may be provided on the reflective layer 120. The protective layer 140 may cover the upper surface of the reflective layer 120. The protective layer 140 may include an insulating material. The protective layer 140 may include a photosensitive material. For example, the protective layer 140 may include an insulating polymer or a photo imageable dielectric (PID). For example, the photosensitive insulating material may include at least one of a photosensitive polyimide (PI), a polybenzoxazole (PBO), a phenol-based polymer, or a benzocyclobutene-based polymer.

An opening OP may be formed in the protective layer 140. The opening OP may penetrate the protective layer 140 to expose the conductive pattern 130. The exposed conductive pattern 130 may serve as a substrate pad for mounting another semiconductor element or electronic element on the wiring board 100. Alternatively, the wiring board 100 may further include an under bump pad provided on the protective layer 140, and the under bump pad may be connected to the conductive pattern 130 through the opening OP.

As the reflective layer 120 covers the first insulating layer 110 and the protective layer 140 is provided on the reflective layer 120, the opening OP of the protective layer 140 may expose at least a portion of the upper surface of the reflective layer 120. In addition, the protective layer 140 may be spaced apart from the upper surface of the first insulating layer 110. Preferably, an inner wall of the opening OP may be spaced apart from the upper surface of the first insulating layer 110 by the reflective layer 120. As illustrated in FIG. 2, the entire inner wall of the opening OP may be disposed on the upper surface of the reflective layer 120. An angle AN formed between the inner wall of the opening OP and the upper surface of the reflective layer 120 exposed by the opening OP may be 90 degrees to 120 degrees. In an embodiment, the angle AN may be greater than 90 degrees and less than 120 degrees. In another embodiment, the angle AN may be greater than or equal to 90 degrees and less than 120 degrees. Still in another embodiment, the angle AN may be greater than 90 degrees and less than or equal to 120 degrees. Still yet in another embodiment, the angle AN may be greater than or equal to 90 degrees and less than or equal to 120 degrees.

When the angle AN between the inner wall of the opening OP and the upper surface of the reflective layer 120 exposed by the opening OP is less than 90 degrees, that is, when an undercut is formed at an end of the protective layer 140 forming the opening OP, the protective layer 140 may be peeled off, or foreign substances may be introduced into the undercut, or a void may be formed in which an underfill material is not filled in the undercut when mounting an electronic element onto the conductive pattern 130.

According to embodiments of the inventive concept, the angle AN between the inner wall of the opening OP and the upper surface of the reflective layer 120 exposed by the opening OP may be greater than 90 degrees. Accordingly, the protective layer 140 may not be easily peeled off from the reflective layer 120, and the foreign substances may not be introduced into the opening OP. In addition, when mounting the electronic component, the underfill material may be filled in the opening OP, easily. That is, the wiring board 100 with improved structural stability and a semiconductor module including the same may be provided.

In the following embodiments, the components described in the embodiments of FIGS. 1 to 6 use the same reference numerals, and for the convenience of explanation, descriptions thereof are omitted or briefly described. That is, the differences between the embodiments of FIGS. 1 to 6 and the embodiments below will be described.

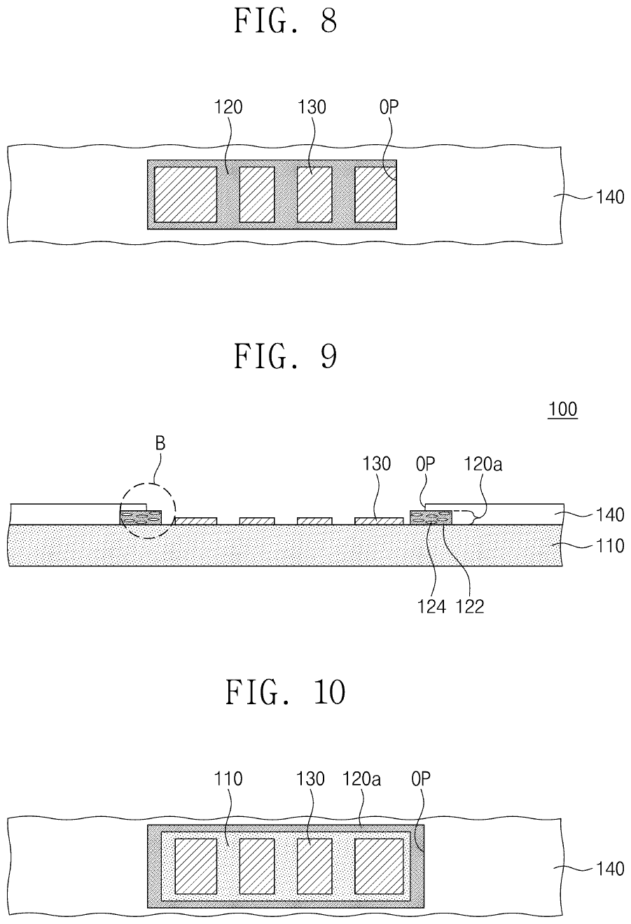

FIG. 7 is a cross-sectional view for explaining a wiring board according to embodiments of the inventive concept. FIG. 8 is a plan view for explaining a wiring board according to embodiments of the inventive concept.

According to FIGS. 7 and 8, a protective layer 140 may cover at least a portion of a conductive pattern 130. In other words, a portion of the conductive pattern 130 may be covered by the protective layer 140, and the other portion of the conductive pattern 130 may be exposed through the opening OP. Accordingly, at least a portion of the inner wall of the opening OP may be disposed on the upper surface of the conductive pattern 130. The inner wall of the opening OP may be spaced apart from the upper surface of the first insulating layer 110 by the reflective layer 120 and the conductive pattern 130. As illustrated in FIG. 8, the entire inner wall of the opening OP may be disposed on the upper surface of the reflective layer 120 or an upper surface of a portion of the conductive pattern 130. An angle formed between the inner wall of the opening OP and the upper surface of the reflective layer 120 exposed by the opening OP may be between 90 degrees and 120 degrees. An angle formed between the inner wall of the opening OP and the upper surface of the portion of the conductive pattern 130 exposed by the opening OP may be between 90 degrees and 120 degrees.

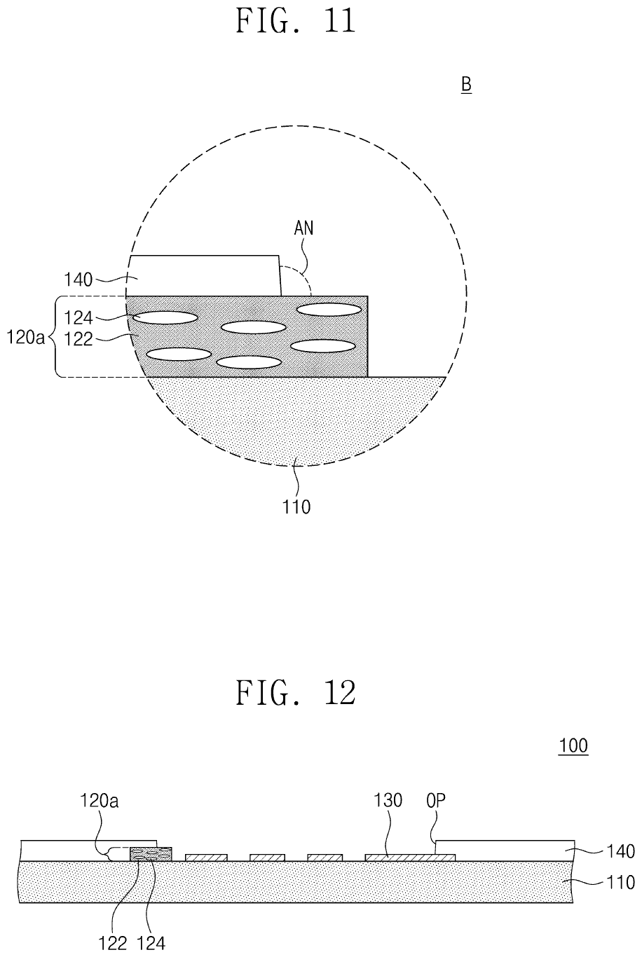

FIG. 9 is a cross-sectional view for explaining a wiring board according to embodiments of the inventive concept. FIG. 10 is a plan view for explaining a wiring board according to embodiments of the inventive concept. FIG. 11 is an enlarged view of region ‘B’ of FIG. 9.

FIGS. 1 to 8 illustrates the reflective layer 120 covers the entire upper surface of the first insulating layer 110, but the inventive concept is not limited thereto.

Referring to FIGS. 9 to 11, a reflective pattern 120a may be provided on the first insulating layer 110 instead of the reflective layer. The reflective pattern 120a may have a closed curve shape when viewed in a plan view. A planar shape of the reflective pattern 120a will be described in detail with the protective layer 140. The reflective pattern 120a may include a second insulating layer 122 and particles 124. The second insulating layer 122 and the particles 124 may be substantially the same as or similar to those described with reference to FIGS. 1 to 6. For example, the particles 124 may be dispersed in the second insulating layer 122, and the particles 124 may have a core portion 125 and a shell portion 126.

A conductive pattern 130 may be disposed on the first insulating layer 110. The conductive pattern 130 may be disposed on an upper surface of the first insulating layer 110. When viewed in a plan view, the conductive pattern 130 may be disposed inside the reflective pattern 120a having the closed curve shape. The conductive pattern 130 may be horizontally spaced from the reflective pattern 120a.

A protective layer 140 may be provided on the first insulating layer 110. The protective layer 140 may cover the upper surface of the first insulating layer 110. The protective layer 140 may cover at least a portion of the reflective pattern 120a. An opening OP may be formed in the protective layer 140. The opening OP may penetrate the protective layer 140 to expose the entire conductive pattern 130. The reflective pattern 120a may extend along an inner wall of the opening OP. The entire inner wall of the opening OP may be disposed on an upper surface of the reflective pattern 120a. Accordingly, the inner wall of the opening OP may be spaced apart from the upper surface of the first insulating layer 110 by the reflective pattern 120a.

As illustrated in FIG. 11, the entire inner wall of the opening OP may be disposed on the upper surface of the reflective pattern 120a. An angle AN formed between the inner wall of the opening OP and the upper surface of the reflective pattern 120a exposed by the opening OP may be 90 to 120 degrees.

Unlike those illustrated in FIGS. 9 to 11, the reflective pattern 120a may not form a closed curve when viewed in a plan view.

FIG. 12 is a cross-sectional view illustrating a wiring board according to embodiments of the inventive concept.

Referring to FIG. 12, a protective layer 140 may cover at least a portion of the conductive pattern 130. In other words, a portion of the conductive pattern 130 may be covered by the protective layer 140, and the other portion of the conductive pattern 130 may be exposed through an opening OP. Accordingly, at least a portion of an inner wall of the opening OP may be disposed on an upper surface of the conductive pattern 130. The inner wall of the opening OP may be separated from the upper surface of the first insulating layer 110 by the reflective pattern 120a or the conductive pattern 130. The entire inner wall of the opening OP may be disposed on the upper surface of the reflective pattern 120a or the upper surface of the portion of the conductive pattern 130. An angle formed between the inner wall of the opening OP and the upper surface of the reflective pattern 120a exposed by the opening OP may be 90 to 120 degrees. An angle formed between the inner wall of the opening OP and the upper surface of the portion of the conductive pattern 130 exposed by the opening OP may be 90 to 120 degrees.

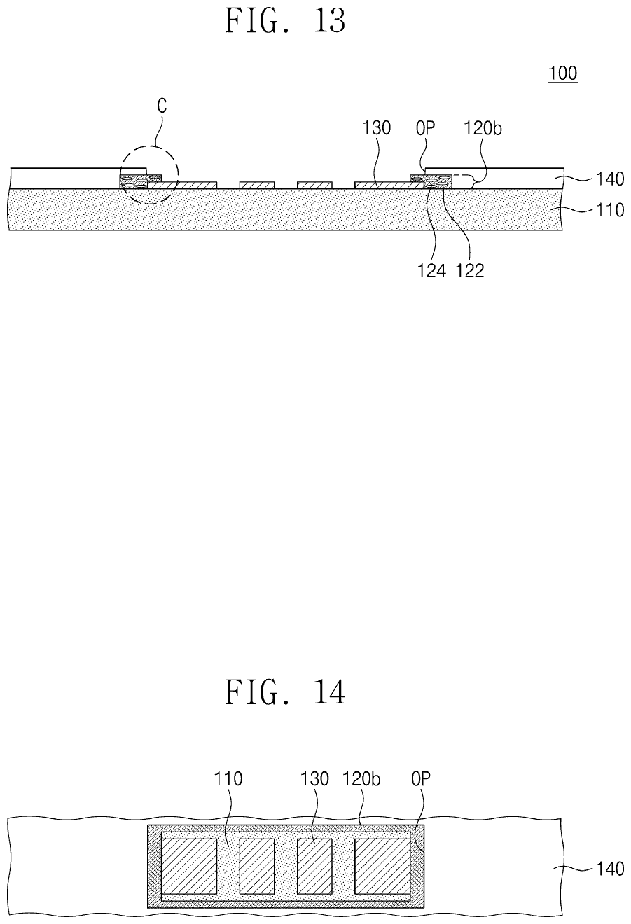

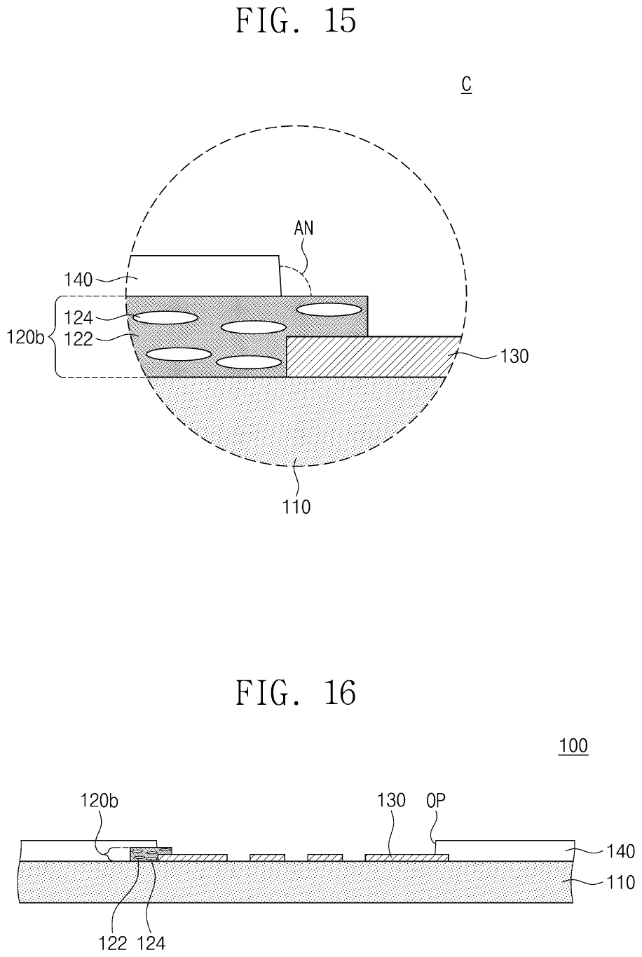

FIG. 13 is a cross-sectional view illustrating a wiring board according to embodiments of the inventive concept. FIG. 14 is a plan view for explaining a wiring board according to embodiments of the inventive concept. FIG. 15 is an enlarged view of region ‘C’ of FIG. 13.

Referring to FIGS. 13 to 15, a reflective pattern 120b may be provided on the first insulating layer 110 instead of the reflective layer. The reflective pattern 120b may have a closed curve shape when viewed in a plan view. The reflective pattern 120b may include a second insulating layer 122 and particles 124. The second insulating layer 122 and the particles 124 may be substantially the same as or similar to those described with reference to FIGS. 1 to 6. For example, the particles 124 may be dispersed in the second insulating layer 122, and the particles 124 may have a core portion 125 and a shell portion 126.

A conductive pattern 130 may be disposed on the first insulating layer 110. The conductive pattern 130 may be disposed on an upper surface of the first insulating layer 110. When viewed in a plan view, the conductive pattern 130 may be disposed inside the reflective pattern 120b having the closed curve shape. The reflective pattern 120b may cover at least a portion of the conductive pattern 130. In other words, a portion of the conductive pattern 130 may be covered by the reflective pattern 120b, and the other portion of the conductive pattern 130 may extend inside the reflective pattern 120b.

A protective layer 140 may be provided on the first insulating layer 110. The protective layer 140 may cover the upper surface of the first insulating layer 110. The protective layer 140 may cover at least a portion of the reflective pattern 120b. An opening OP may be formed in the protective layer 140. The opening OP may penetrate the protective layer 140 to expose the entire conductive pattern 130. The reflective pattern 120b may extend along an inner wall of the opening OP. The entire inner wall of the opening OP may be disposed on the upper surface of the reflective pattern 120b. Accordingly, the inner wall of the opening OP may be spaced from the upper surface of the first insulating layer 110 by the reflective pattern 120b.

As illustrated in FIG. 15, the entire inner wall of the opening OP may be disposed on the upper surface of the reflective pattern 120b. An angle AN formed between the inner wall of the opening OP and the upper surface of the reflective pattern 120b exposed by the opening OP may be 90 degrees to 120 degrees.

Unlike those illustrated in FIGS. 13 to 15, the reflective pattern 120b may not form a closed curve when viewed in a plan view.

FIG. 16 is a cross-sectional view illustrating a wiring board according to embodiments of the inventive concept.

Referring to FIG. 16, a protective layer 140 may cover at least a portion of the conductive pattern 130. In other words, a portion of the conductive pattern 130 may be covered by the protective layer 140, and the other portion of the conductive pattern 130 may be exposed through the opening OP. Accordingly, at least a portion of an inner wall of an opening OP may be disposed on an upper surface of the conductive pattern 130. An inner wall of the opening OP may be spaced apart from an upper surface of the first insulating layer 110 by the reflective pattern 120b and the conductive pattern 130. The entire inner wall of the opening OP may be disposed on an upper surface of the reflective pattern 120b or an upper surface of the portion of the conductive pattern 130. In detail, a portion of the inner wall of the opening OP may be disposed on the upper surface of the reflective pattern 120b, and the other portion of the inner wall of the opening OP may be disposed on the upper surface of the conductive pattern 130. An angle formed between the inner wall of the opening OP and the upper surface of the reflective pattern 120b exposed by the opening OP may be 90 to 120 degrees. An angle formed between the inner wall of the opening OP and the upper surface of the portion of the conductive pattern 130 exposed by the opening OP may be 90 to 120 degrees.

According to other embodiments, at least a portion of the conductive pattern 130 may not be covered by the reflective pattern 120b and may be spaced apart from the reflective pattern 120b.

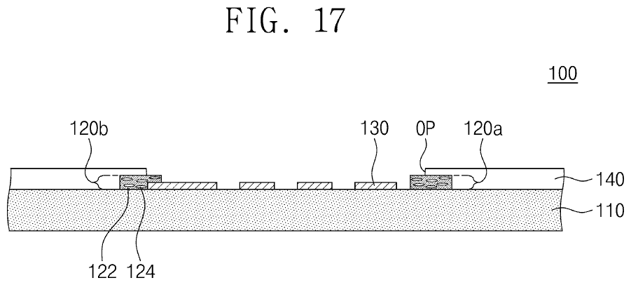

FIG. 17 is a cross-sectional view for explaining a wiring board according to embodiments of the inventive concept.

Referring to FIG. 17, a reflective pattern may include a portion 120b covering a portion of the conductive pattern 130 and a portion 120a that does not cover the conductive pattern 130 and is horizontally spaced from the conductive pattern 130. The protective layer 140 may be spaced from the upper surface of the first insulating layer 110 by the reflective pattern 120a and 120b.

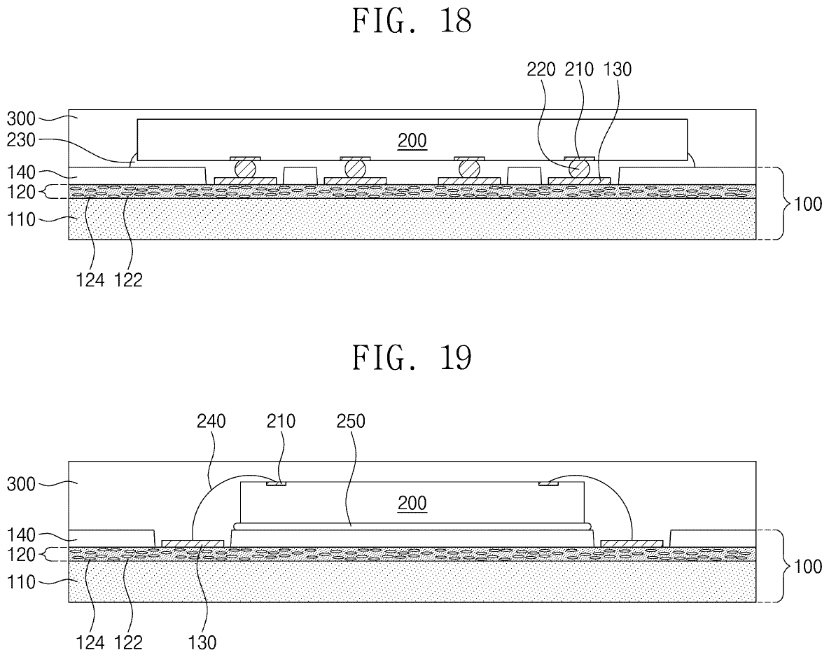

FIGS. 18 and 19 are cross-sectional views for explaining a semiconductor module according to embodiments of the inventive concept.

Referring to FIG. 18, a wiring board 100 may be provided. The wiring board 100 may be the same as or similar to that described with reference to FIGS. 1 to 17. For example, the wiring board 100 may include a first insulating layer 110, a reflective layer 120 or a reflective pattern 120a and 120b (refer to FIGS. 9 to 17) disposed on the first insulating layer 110, a conductive pattern 130 on the first insulating layer 110, and a protective layer 140 disposed on the first insulating layer 110. The protective layer 140 may have an opening whose inner wall is disposed on the upper surface of the reflective layer 120 or the reflective pattern 120a and 120b. At least a portion of the conductive pattern 130 may be exposed by the opening without being covered by the protective layer 140.

Although not illustrated, external terminals may be provided below the wiring board 100. The external terminals may be disposed on a lower surface of the wiring board 100 and may be electrically connected to wirings in the wiring board 100. The external terminals may include solder balls or solder bumps.

A semiconductor chip 200 may be disposed on a wiring board 100. A lower surface of the semiconductor chip 200 facing the wiring board 100 may be an active surface. The semiconductor chip 200 may have chip pads 210 provided on the lower surface of the semiconductor chip 200. The semiconductor chip 200 may include silicon (Si). As illustrated in FIG. 18, the semiconductor chip 200 may be mounted on the wiring board 100 in a flip chip manner. For example, the semiconductor chip 200 may have chip terminals 220 provided on the chip pads 210. The chip terminals 220 may be connected to the chip pads 210 of the semiconductor chip 200 and the conductive pattern 130 of the wiring board 100. The chip terminals 220 may include solder balls or solder bumps. The semiconductor chip 200 may be electrically connected to the external terminals through the conductive pattern 130 of the wiring board 100.

In FIG. 18, the semiconductor chip 200 is illustrated as being provided face down, but the inventive concept is not limited thereto. As illustrated in FIG. 19, the semiconductor chip 200 may be provided face up.

Referring to FIG. 19, the semiconductor chip 200 may be disposed on the wiring board 100. A lower surface of the semiconductor chip 200 facing the wiring board 100 may be an inactive surface, and an upper surface of the semiconductor chip 200 may be an active surface. The semiconductor chip 200 may be attached to the upper surface of the wiring board 100, preferably, to the upper surface of the protective layer 140, using an adhesive layer 250. The semiconductor chip 200 may have the chip pads 210 provided on the upper surface of the semiconductor chip 200. The semiconductor chip 200 may be mounted on the wiring board 100 by a boding wire method. For example, bonding wires 240 may be provided that extend from the upper surface of the chip pads 210 to the upper surface of the exposed conductive pattern 130 and may be connected to the chip pads 210 and the conductive pattern 130. The semiconductor chip 200 may be electrically connected to the wiring board 100 by the bonding wire 240. Hereinafter, the description will continue based on the embodiment of FIG. 18.

According to other embodiments, the semiconductor chip 200 provided on the wiring board 100 may not include a transistor therein. That is, unlike the illustrated embodiment, an interposer substrate, not a chip, may be disposed on the wiring board 100. The interposer substrate may include silicon (Si). The interposer substrate may have a circuit for wiring on an upper surface thereof. The interposer substrate may be surrounded by a mold layer as needed. Here, the mold layer is a component that is distinct from a mold layer 300 described below. The mold layer may embed the interposer substrate on the wiring board 100. That is, the interposer substrate may be covered by the mold layer. At least one element (e.g., an electronic element required in a chip or semiconductor package including a transistor) may be provided on the interposer substrate. The at least one element may be electrically connected to the wiring board 100 and the interposer substrate using the mold layer or a via penetrating the interposer substrate. Alternatively, when the mold layer is not provided, the at least one element may be directly mounted on the interposer substrate. When a plurality of elements are provided, the elements may be electrically connected to each other through the interposer substrate. If necessary, an additional substrate may be provided between the at least one element and the interposer substrate (or the mold layer) to support the at least one element. In this case, the at least one element may be mounted on the additional substrate, and the at least one element may be electrically connected to the interposer substrate and the wiring board 100 through the additional substrate and the via. Hereinafter, the description will continue based on the semiconductor chip 200 being provided on the wiring board 100.

With continued reference to FIG. 18, a molding layer 300 may be provided on the wiring board 100. The molding layer 300 may cover the semiconductor chip 200 on the upper surface of the wiring board 100. For example, the molding layer 300 may cover an upper surface and side surfaces of the semiconductor chip 200. The molding layer 300 may fill a space between the semiconductor chip 200 and the wiring board 100. The molding layer 300 may include an insulating material such as an epoxy-based polymer. For example, the molding layer 300 may include an epoxy molding compound (EMC). Alternatively, a space between the semiconductor chip 200 and the wiring board 100 may be filled with an underfill member 230. The underfill member 230 may fill the space between the semiconductor chip 200 and the wiring board 100 and may surround the chip terminals 220.

FIGS. 20 to 25 are cross-sectional views for explaining a method of manufacturing a wiring board of the inventive concept.

Referring to FIG. 20, a first insulating layer 110 may be provided. The first insulating layer 110 may be one of insulating patterns provided in a wiring board. In detail, the first insulating layer 110 may be an insulating pattern provided at the uppermost one of the insulating patterns.

A reflective layer 120 may be formed. For example, particles 124 may be impregnated into an insulating member. The particles 124 may be the same as or similar to those described with reference to FIGS. 4 to 6. The insulating member impregnated with the particles 124 may be applied on an upper surface of the first insulating layer 110. In this case, the particles 124 may be aligned so that the particles 124 lie in a direction parallel to the upper surface of the first insulating layer 110. Thereafter, the insulating member may be hardened to form a second insulating layer 122. Alternatively, the reflective layer 120 may be formed on an additional substrate using the same method as described above, and then the reflective layer 120 may be transferred onto the upper surface of the first insulating layer 110. According to other embodiments, the insulating member may be impregnated with spherical particles, the insulating member may be hardened to form the second insulating layer 122, and then the second insulating layer 122 may be pressed to form plate-shaped particles 124. In the same method as described above, the reflective layer 120 may be formed on the upper surface of the first insulating layer 110, or the formed reflective layer 120 may be transferred onto the upper surface of the first insulating layer 110.

A conductive pattern 130 may be formed on the reflective layer 120. For example, after forming a conductive layer on the upper surface of the reflective layer 120, the conductive layer may be patterned to form the conductive pattern 130. If necessary, before forming the conductive layer, the reflective layer 120 and the first insulating layer 110 may be patterned to form a via hole for forming a via portion for connecting to a wiring in the first insulating layer 110. The conductive layer may fill the via hole, and a portion of the conductive layer disposed in the via hole may be formed as a via for vertical wiring.

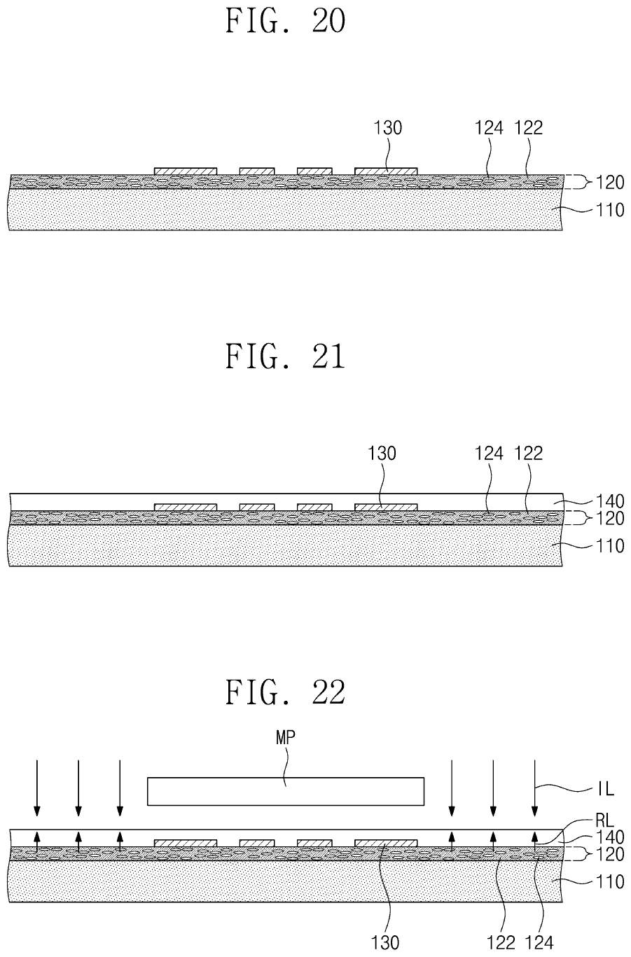

Referring to FIG. 21, a protective layer 140 may be formed on the reflective layer 120. For example, an insulating material may be applied or deposited on the upper surface of the reflective layer 120 to form the protective layer 140. The protective layer 140 may cover the conductive pattern 130 on the upper surface of the reflective layer 120. The protective layer 140 may include a photosensitive material. For example, the protective layer 140 may include an insulating polymer or a photo imageable dielectric (PID). For example, the photosensitive insulating material may include at least one of a photosensitive polyimide (PI), a polybenzoxazole (PBO), a phenol-based polymer, or a benzocyclobutene-based polymer.

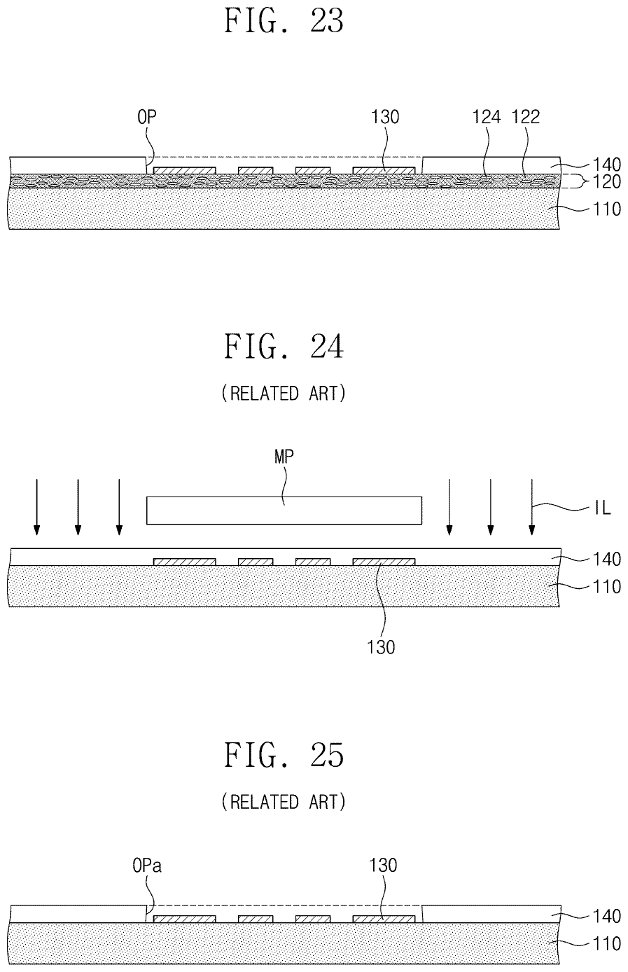

Referring to FIG. 22, a mask pattern MP may be provided on the protective layer 140. The mask pattern MP may be vertically spaced from an upper surface of the protective layer 140. The mask pattern MP may have a pattern covering a region where an opening OP (refer to FIG. 23) is to be formed. For example, the mask pattern MP may be disposed on the conductive pattern 130. The mask pattern MP may vertically overlap with the conductive pattern 130.

An exposure process may be performed on the protective layer 140. For example, the irradiated light IL irradiated to the mask pattern MP may pass through the pattern of the mask pattern MP and irradiate to the protective layer 140, and a portion of the protective layer 140 irradiated with the irradiated light IL may be hardened. A portion of the irradiated light IL may penetrate the protective layer 140 and may reach the reflective layer 120. The portion of the irradiated light IL may be reflected by the reflective layer 120, preferably by the core portion 125 of the particles 124 of the reflective layer 120. A reflected light RL reflected by the particles 124 may reach the protective layer 140.

According to embodiments of the inventive concept, a portion of the irradiated light IL used in the exposure process that passes through the protective layer 140 may be reflected by the reflective layer 120, and the reflected light RL may also be absorbed by the reflective layer 120. Accordingly, a lower portion of the protective layer 140 may also absorb sufficient light, and defects such as peeling caused by the lower portion of the protective layer 140 not being hardened may not occur. In other words, a method of manufacturing a wiring board and a semiconductor module with less defects may be provided.

Referring to FIG. 23, a development process may be performed on the protective layer 140 to form an opening OP. For example, during the development process, a portion of the protective layer 140 that is not irradiated with the light IL and RL in the exposure process may be removed to form the opening OP. As described above, the exposure amount may be large at the lower portion of the protective layer 140. Accordingly, an inner wall of the opening OP may be formed to be inclined with respect to an upper surface of the reflective layer 120 exposed by the opening OP. For example, a width of the lower portion of the opening OP may be smaller than a width of an upper portion of the opening OP. An angle formed between the inner wall of the opening OP and the upper surface of the reflective layer 120 may be greater than 90 degrees.

Alternatively, when the reflective layer 120 is not provided, an angle formed between the inner wall of the opening OP and the upper surface of the reflective layer 120 may be less than 90 degrees.

As shown in FIG. 24, a conductive pattern 130 may be formed on the first insulating layer 110, and a protective layer 140 covering the conductive pattern 130 may be formed on the first insulating layer 110. An exposure process may be performed on the protective layer 140. For example, irradiated light IL irradiated on the mask pattern MP may pass through the pattern of the mask pattern MP and may be irradiated on the protective layer 140, and a portion of the protective layer 140 irradiated with the irradiated light IL may be hardened. A portion of the irradiated light IL may be absorbed into the first insulating layer 110 by transmitting through the protective layer 140. Accordingly, the exposure amount of the lower portion of the protective layer 140 may be less than that of the upper portion.

Referring to FIG. 25, a development process may be performed on the protective layer 140 to form an opening OPa. For example, during the developing process, a portion of the protective layer 140 that is not irradiated with the light IL in the exposure process may be removed to form the opening OPa. As the exposure amount to the lower portion of the protective layer 140 is small, a portion of the lower portion of the protective layer 140 adjacent to the opening OPa may be removed together. For example, a width of a lower portion of the opening OPa may be greater than a width of an upper portion of the opening OPa. An angle formed between the inner wall of the opening OPa and the upper surface of the reflective layer 120 may be smaller than 90 degrees. That is, an undercut region may be formed at one end of the protective layer 140 adjacent to the opening OPa. When the undercut is formed at the end of the protective layer 140 forming the opening OPa, the protective layer 140 may be peeled off, or foreign substances may be introduced into the undercut, or a void may be formed in which an underfill material is not filled in the undercut when mounting an electronic element onto the conductive pattern 130.

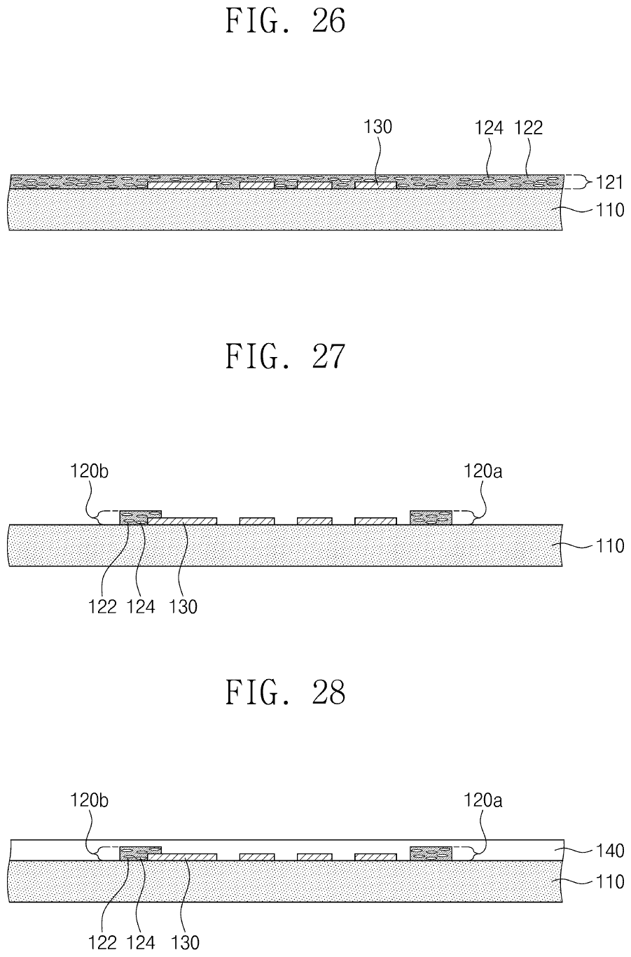

FIGS. 26 to 29 are cross-sectional views illustrating a method of manufacturing a wiring board of the inventive concept.

Referring to FIG. 26, a first insulating layer 110 may be provided. The first insulating layer 110 may be one of insulating patterns provided in a wiring board.

A conductive pattern 130 may be formed on the first insulating layer 110. For example, a conductive layer may be formed on an upper surface of the first insulating layer 110, and then the conductive layer may be patterned to form the conductive pattern 130. If necessary, before forming the conductive layer, the first insulating layer 110 may be patterned to form a via hole for forming a via portion for connecting with the wiring in the first insulating layer 110. The conductive layer may fill the via hole, and a portion of the conductive layer disposed in the via hole may be formed as a via for vertical wiring.

A preliminary reflective layer 121 may be formed. For example, particles 124 may be impregnated into an insulating member. The particles 124 may be the same as or similar to those described with reference to FIGS. 4 to 6. The insulating member impregnated with the particles 124 may be applied onto an upper surface of the first insulating layer 110. In this case, the particles 124 may be aligned so that the particles 124 lie in a direction parallel to the upper surface of the first insulating layer 110. Thereafter, the insulating member may be hardened to form the second insulating layer 122. Alternatively, the preliminary reflective layer 121 may be formed on an additional substrate using the same method as described above, and then the preliminary reflective layer 121 may be transferred onto the upper surface of the first insulating layer 110. The preliminary reflective layer 121 may cover the conductive pattern 130 on the upper surface of the first insulating layer 110.

Referring to FIG. 27, the preliminary reflective layer 121 may be patterned to form a reflective pattern 120a and 120b. The reflective pattern 120a and 120b may have a closed curve shape extending along a boundary of a region where an opening is to be formed in the process described below. When viewed in a plan view, the conductive pattern 130 may be disposed inside the closed curve-shaped reflective pattern 120a and 120b. The portion 120a of the reflective pattern 120a and 120b may cover at least a portion of the conductive pattern 130, and the other portion of the reflective pattern 120a and 120b may be horizontally spaced from the conductive pattern 130.

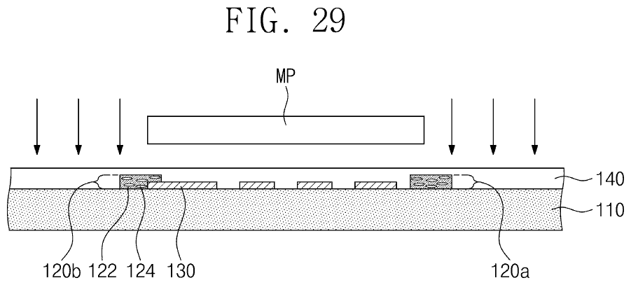

Referring to FIG. 28, a protective layer 140 may be formed on the first insulating layer 110. For example, an insulating material may be applied or deposited on the upper surface of the first insulating layer 110 to form the protective layer 140. The protective layer 140 may cover the conductive pattern 130 and the reflective pattern 120a and 120b on the upper surface of the first insulating layer 110. The protective layer 140 may include a photosensitive material. For example, the protective layer 140 may include an insulating polymer or a photo imageable dielectric (PID).

Referring to FIG. 29, a mask pattern MP may be provided on the protective layer 140. The mask pattern MP may be spaced vertically from the upper surface of the protective layer 140. The mask pattern MP may have a pattern that covers a region where the opening is to be formed. For example, the mask pattern MP may be disposed on the conductive pattern 130. The mask pattern MP may vertically overlap with the conductive pattern 130.

An exposure process may be performed on the protective layer 140. For example, the irradiated light irradiated to the mask pattern MP may pass through the pattern of the mask pattern MP and may irradiate to the protective layer 140, and a portion of the protective layer 140 irradiated with the irradiated light may be hardened. The irradiated light may penetrate the protective layer 140 in a region adjacent to the opening and may reach the reflective pattern 120a and 120b. The irradiated light may be reflected by the reflective pattern 120a and 120b, preferably by the core portion 125 of the particles 124 of the reflective pattern 120a and 120b. The reflected light reflected by the particles 124 may reach the protective layer 140.

Referring again to FIG. 17, a development process may be performed on the protective layer 140 to form an opening OP. For example, during the development process, a portion of the protective layer 140 that is not irradiated with the light in the exposure process may be removed to form the opening OP. The exposure amount may be large at the lower portion of the protective layer 140. Accordingly, an inner wall of the opening OP may be formed to be inclined with respect to the upper surface of the reflective layer 120 exposed by the opening OP.

According to embodiments of the inventive concept, the wiring board may have the angle greater than 90 degrees between the inner wall of the opening of the protective layer and the upper surface of the reflective layer. Accordingly, the protective layer may not be easily peeled off from the reflective layer, and the foreign substances may not be introduced into the opening. In addition, the underfill material may be easily filled into the opening when mounting the electronic device. That is, the wiring board with the improved structural stability and the semiconductor module including the same may be provided.

In addition, the core portion in the reflective layer may have the plate shape, and the core portion may include the metal material. Accordingly, the heat may be easily transferred along the particles in the horizontal direction in the reflective layer. That is, the heat transfer in the horizontal direction in the wiring board may be facilitated, and the wiring board with the improved heat dissipation efficiency and the semiconductor module including the same may be provided.

The particles provided in the reflective layer may have insulating characteristics and the transparent shell portion may surround the core portion. Accordingly, the electrical short circuit due to the core portion in the reflective layer may not occur. That is, the wiring board with the improved electrical characteristics and the semiconductor module including the same may be provided. As the outer surface roughness of the core portion increases, the adhesion of the shell portion to the outer surface of the core portion may be further improved. Alternatively, the intermediate layer may firmly bond the core portion and the shell portion. Accordingly, the shell portion may not be peeled off from the core portion, and the electrical insulation characteristics provided by the shell portion to the particles may be improved.

In the method of manufacturing the wiring board according to embodiments of the inventive concept, some of the irradiated light used in the exposure process that passes through the protective layer may be reflected by the reflective layer, and the reflected light may also be absorbed by the reflective layer. Accordingly, the lower portion of the protective layer may absorb sufficient light, and the defects such as peeling caused by the lower portion of the protective layer not being hardened may not occur. In other words, the method of manufacturing the wiring board and the semiconductor module with less defects may be provided.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A wiring board comprising:
a first insulating layer;
a reflective layer disposed on an upper surface of the first insulating layer;
a conductive pattern on an upper surface of the reflective layer; and
a protective layer on the upper surface of the reflective layer and having an opening exposing at least a portion of the conductive pattern,
wherein the reflective layer includes:
a second insulating layer; and
particles dispersed in the second insulating layer,
wherein each of the particles includes:
a core portion; and
a shell portion surrounding the core portion, and
wherein a light reflectivity of the core portion is higher than a light reflectivity of the shell portion.

2. The wiring board of claim 1, wherein the shell portion includes a transparent material, and
wherein the core portion includes a metal material.

3. The wiring board of claim 2, wherein the shell portion includes prepreg, transparent polymer, or transparent ceramic, and
wherein the core portion includes chromium (Cr) or silver (Ag).

4. The wiring board of claim 1, wherein each of the particles has a plate shape, a flat ellipsoid shape, or a combination thereof, and
wherein a major axis of each of the particles is substantially parallel to the upper surface of the reflective layer.

5. The wiring board of claim 1, wherein a thickness of each of the particles in a direction perpendicular to the upper surface of the reflective layer is smaller than a width of each of the particles in a direction parallel to the upper surface of the reflective layer.

6. The wiring board of claim 1, wherein the opening exposes at least a portion of the upper surface of the reflective layer, and
wherein an angle formed between the upper surface of the reflective layer exposed by the opening and an inner wall of the opening is 90 to 120 degrees.

7. The wiring board of claim 1, wherein a thickness of the core portion in a direction perpendicular to the upper surface of the reflective layer is 0.01 micrometer to 1 micrometer, and
wherein a width of the core portion in a direction parallel to the upper surface of the reflective layer is 0.1 micrometer to 10 micrometers.

8. The wiring board of claim 1, wherein a thickness of the shell portion in a direction perpendicular to the upper surface of the reflective layer is 10 nanometers to 500 nanometers.

9. The wiring board of claim 1, wherein a surface roughness of an outer surface of the core portion is greater than that of an outer surface of the shell portion.

10. The wiring board of claim 1, wherein each of the particles further includes an intermediate layer interposed between the core portion and the shell portion, and
wherein the intermediate layer has a silane bonding group.

11. A wiring board comprising:
a first insulating layer;
a conductive pattern on an upper surface of the first insulating layer;
a reflective pattern on the upper surface of the first insulating layer; and
a protective layer disposed on at least a portion of the reflective pattern on the first insulating layer,
wherein the protective layer has an opening exposing at least a portion of the conductive pattern, and an inner wall of the opening is separated from the upper surface of the first insulating layer by the reflective pattern or the conductive pattern,
wherein the reflective pattern includes:
a second insulating layer; and
particles dispersed in the second insulating layer,
wherein each of the particles includes:
a core portion; and
a shell portion surrounding the core portion.

12. The semiconductor module of claim 11, wherein the reflective pattern extends along the inner wall of the opening, and
wherein the entire inner wall of the opening is disposed on an upper surface of the reflective pattern.

13. The semiconductor module of claim 12, wherein at least a portion of the reflective pattern is horizontally spaced from the conductive pattern, and
wherein the entire conductive pattern is exposed by the opening.

14. The semiconductor module of claim 11, wherein at least a portion of the inner wall of the opening is disposed on an upper surface of the reflective pattern, and
wherein another portion of the inner wall of the opening is disposed on an upper surface of the conductive pattern.

15. The semiconductor module of claim 11, wherein the reflective pattern covers at least a portion of the conductive pattern.

16. The semiconductor module of claim 11, wherein the shell portion includes a transparent material, and
wherein the core portion includes a metal material.

17. The semiconductor module of claim 11, wherein each of the particles has a plate shape, a flat ellipsoid shape, or a combination thereof,
wherein a thickness of each of the particles in a direction perpendicular to the upper surface of the first insulating layer is smaller than a width of each of the particles in a direction parallel to the upper surface of the first insulating layer.

18. The semiconductor module of claim 11, wherein an angle formed between the inner wall of the opening and an upper surface of the conductive pattern exposed by the opening or an angle formed between the inner wall of the opening and an upper surface of the reflective pattern exposed by the opening is 90 to 120 degrees.

19. A semiconductor module comprising:
the wiring board of claim 1;
a semiconductor chip mounted on the wiring board; and
a molding layer covering the semiconductor chip on the wiring board.

20. A semiconductor module comprising:
the wiring board of claim 11;
a semiconductor chip mounted on the wiring board; and
a molding layer covering the semiconductor chip on the wiring board.
